(19) United States
(12) Patent Application Publication
(10) Pub. No.: US 2009/0239080 A1
(43) Pub. Date: Sep. 24, 2009

(54) PHOTOSENSITIVE INSULATION RESIN COMPOSITION AND CURED PRODUCT THEREOF

(75) Inventors: Atsushi Ito, Tokyo (JP); Hirofumi Goto, Tokyo (JP); Hirofumi Sasaki, Tokyo (JP)

Correspondence Address: DITTHAVONG MORI & STEINER, P.C., 918 Prince St., Alexandria, VA, 22314, US

(73) Assignee: JSR CORPORATION, Tokyo (JP)

(21) Appl. No.: 12/439,006

(22) PCT Filed: Jul. 23, 2007
(86) PCT No.: PCT/JP2007/064433

§ 371 Date: Feb. 26, 2009

(30) Foreign Application Priority Data
Aug. 29, 2006 (JP) 2006-232301

(51) Int. Cl. G03F 7/004; B32B 27/06

(52) U.S. Cl. 428/411.1; 430/270.1; 430/280.1

(57) ABSTRACT

An object of the present invention is to provide a cured product which is excellent in characteristics such as an electric insulation property, a heat impact resistance, an adhesive property and the like and to provide a photosensitive insulation resin composition from which the above cured product can be obtained and which is suited to uses such as an interlayer insulation film, a surface protecting layer and the like in semiconductor elements. The photosensitive insulation resin composition according to the present invention is characterized by comprising (A) a copolymer comprising 10 to 99 mole % of a constitutional unit (A1) represented by the following Formula (1) and 90 to 1 mole % of a constitutional unit (A2) represented by the following Formula (2) (provided that the total of all constitutional units constituting the above copolymer (A) is 100 mole %):

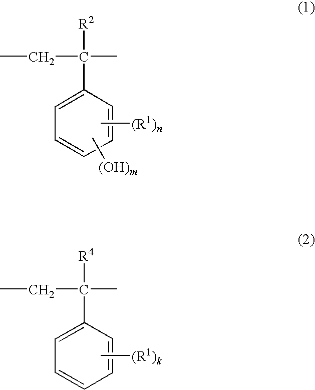

(wherein R¹ represents an alkyl group having 1 to 4 carbon atoms, an alkoxy group or an aryl group; R² represents a hydrogen atom or methyl; m is an integer of 1 to 3, and n is an integer of 0 to 3; and m+n≦5; R³ represents an alkyl group having 1 to 4 carbon atoms, an alkoxy group or an aryl group; R⁴ represents a hydrogen atom or methyl; and k is an integer of 0 to 3), (B) a compound (B1) having an oxetanyl group, (C) a photosensitive acid generator, (D) a solvent and (F) cross-linked fine particles.

### BACKGROUND OF THE INVENTION

The present invention relates to a photosensitive insulation resin composition used for a surface protecting layer (an overcoat film), an interlayer insulation film (a passivation film), an adhesive for laminating chips and the like for semiconductors and an insulating cured product obtained by curing the same. More specifically, it relates to a cured product which is excellent in an electrical insulation property as a permanent film resist and which is excellent further in characteristics such as an adhesive property, a heat impact resistance and the like and a photosensitive insulation resin composition which provides the above cured product.

### RELATED ART

Polyimide base resins and polybenzoxazole base resins which are excellent in a heat resistance, mechanical characteristics and the like have so far widely been used for an interlayer insulation film, a surface protecting layer and the like which are used for semiconductor elements in electronic devices. Further, in order to improve a productivity and enhance a film forming accuracy, photosensitive polyimides and photosensitive polybenzoxazole base resins which are provided with a photosensitivity have been investigated in many cases. For example, positive type photosensitive resin compositions comprising a polyimide precursor and a quinone diazide compound are described in a patent document 1 (Japanese Patent Application Laid-Open No. 5996/1993) and a patent document 2 (Japanese Patent Application Laid-Open No. 98601/2000), and positive type photosensitive resin compositions comprising a polybenzoxazole precursor and a quinone diazide compound are described in a patent document 3 (Japanese Patent Application Laid-Open No. 237736/1999). Further, negative type photosensitive resin compositions prepared by introducing an optical cross-linking group into a polyimide precursor via an ester bond or an ionic bond have been put to practical use as well. However, the above photosensitive resin compositions involve problems such as a film reduction (volume shrinkage ratio) after curing, necessity of multistage baking in curing, atmosphere controlling and the like, and the problem that they are less liable to be put into industrial operation is pointed out.

Further, negative type photosensitive insulation resin compositions prepared by using a polyphenylene oxide base resin are described as well in a patent document 4 (Japanese Patent Application Laid-Open No. 33964/2001). However, the above photosensitive insulation resin compositions involve problems in terms of a balance between the respective performances such as a resolution, an electric insulation property, a heat impact property, an adhesive property and the like.

Then, in order to solve the problems described above, photosensitive insulation resin compositions prepared by using an alkali-soluble resin having a phenolic hydroxyl group such as a novolac resin, polyhydroxystyrene and the like are proposed (for example, a patent document 5 (Japanese Patent Application Laid-Open No. 139835/2002), a patent document 6 (Japanese Patent Application Laid-Open No. 215802/2003), a patent document 7 (Japanese Patent Application Laid-Open No. 45879/1993), a patent document 8 (Japanese Patent Application Laid-Open No. 130666/1994) and a patent document 9 (Japanese Patent Application Laid-Open No. 146556/1995). The alkali-soluble resins used in the above resin compositions are used in order to make it possible to carry out development by an alkaline aqueous solution. It is described in, for example, the patent document 5 and the patent document 6 that a film formed by using an alkali-soluble resin having a phenolic hydroxyl group has a satisfactory developing property by an alkaline aqueous solution. Further, it is suggested as well that a molecular weight of the alkali-soluble resin exerts an influence on a resolution, a heat impact property and a heat resistance of an insulating film obtained.

However, it is not suggested in the above patent documents that the characteristics other than the characteristics described above can be improved by the alkali-soluble resins, and effects depending on the kind of the alkali-soluble resins are by no means suggested as well. In particular, it is described that the electric insulation property is controlled by an amount of a cross-linking agent and that the heat impact property is improved by adding cross-linked fine particles. However, in conventional photosensitive resin compositions, a heat impact property has been improved only to a slight extent even by adding cross-linked fine particles.

Further, radial ray-sensitive resin compositions comprising an alkali-soluble resin, an epoxy compound and a compound having an oxetanyl group in a molecule are disclosed in a patent document 10 (Japanese Patent Application Laid-Open No. 60683/1999). It is disclosed in the above patent document that a thermal sagging phenomenon can be prevented by using an oxetanyl group-containing compound, but effects other than the above effect are by no means suggested. Further, it is suggested that a molecular weight of the alkali-soluble resin exerts an influence on a resolution, a developing property and a plating liquid resistance, but it is not suggested that characteristics other than the above characteristics, particularly the electric insulation property can be improved by the alkali-soluble resin, and effects depending on the kind of the alkali-soluble resins are by no means suggested as well.

Photosensitive resin compositions comprising a binder polymer, a photopolymerizable compound having at least one polymerizable cyclic ether group in a molecule and a photoacid generator are disclosed in a patent document 11 (International Publication No. 01-22165), wherein styrene base resins are disclosed as the example of the binder polymer described above, and oxetane compounds and epoxy compounds are disclosed as the examples of the photopolymerizable compound described above. It is disclosed in the above patent document that a sensitivity, a peeling characteristic and a pattern form of the photosensitive resin compositions are enhanced by using the oxetane compounds and the epoxy compounds, but it is not suggested that the electric insulation property can be improved by the alkali-soluble resin, and effects depending on the kind of the alkali-soluble resins are by no means suggested as well.

Patent document 1: Japanese Patent Application Laid-Open No. 5996/1993
Patent document 2: Japanese Patent Application Laid-Open No. 98601/2000
Patent document 3: Japanese Patent Application Laid-Open No. 237736/1999
Patent document 4: Japanese Patent Application Laid-Open No. 33964/2001
Patent document 5: Japanese Patent Application Laid-Open No. 139835/2002
Patent document 6: Japanese Patent Application Laid-Open No. 215802/2003
Patent document 7: Japanese Patent Application Laid-Open No. 45879/1993
Patent document 8: Japanese Patent Application Laid-Open No. 130666/1994

Patent document 9: Japanese Patent Application Laid-Open No. 146556/1995

Patent document 10: Japanese Patent Application Laid-Open No. 60683/1999
Patent document 11: International Publication No. 01-22165

### DISCLOSURE OF THE INVENTION

The present invention tries to solve the problems involved in the conventional techniques described above, and an object thereof is to provide a cured product which is excellent in characteristics such as an electric insulation property, a heat impact resistance, an adhesive property and the like. Further, another object thereof is to provide a photosensitive insulation resin composition from which the above cured product can be obtained and which is suited to uses such as an interlayer insulation film, a surface protecting layer and the like in semiconductor elements.

Intensive researches have been repeated by the present inventors in order to solve the problems described above, and they have found that a cured product obtained is notably improved in an electric insulation property and a heat impact resistance by using a resin having a specific structure and a specific constitutional ratio among alkali-soluble resins having a phenolic hydroxyl group in a photosensitive insulation resin composition and that adding an oxetanyl group-containing compound makes it possible to enhance the curing speed and reduce generation of an outgas in curing to prevent voids from being produced and provides a cured product having an excellent adhesive property. Thus, they have come to complete the present invention.

That is, the photosensitive insulation resin composition according to the present invention is characterized by comprising (A) a copolymer comprising 10 to 99 mole % of a constitutional unit (A1) represented by the following Formula (1) and 90 to 1 mole % of a constitutional unit (A2) represented by the following Formula (2) (provided that the total of all constitutional units constituting the above copolymer (A) is 100 mole %):

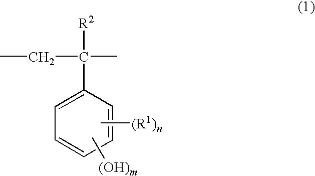

(wherein R¹ represents an alkyl group having 1 to 4 carbon atoms, an alkoxy group or an aryl group; R² represents a hydrogen atom or methyl; m is an integer of 1 to 3, and n is an integer of 0 to 3; and m+n≦5):

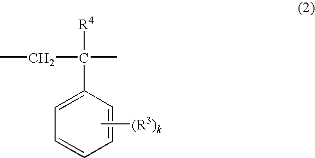

(wherein R³ represents an alkyl group having 1 to 4 carbon atoms, an alkoxy group or an aryl group; R⁴ represents a hydrogen atom or methyl; and k is an integer of 0 to 3), (B) a compound (B1) having an oxetanyl group, (C) a photosensitive acid generator, (D) a solvent and (F) cross-linked fine particles.

The copolymer (A) described above comprises preferably 70 to 95 mole % of the constitutional unit (A1) represented by Formula (1) described above (provided that the total of all constitutional units constituting the above copolymer (A) is 100 mole %).

The photosensitive insulation resin composition described above further comprises preferably a compound (B2) having an epoxy group.

Assuming that the total of the compound (B1) having an oxetanyl group and the compound (B2) having an epoxy group is 100 parts by mass, a content of the compound (B1) having an oxetanyl group is preferably 40 to 60 parts by mass, and a content of the compound (B2) having an epoxy group is preferably 60 to 40 parts by mass.

The constitutional unit (A2) described above is represented preferably by the following Formula (2′):

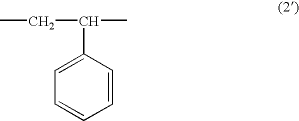

The photosensitive insulation resin composition described above further comprises preferably a phenol compound (a).

The cross-linked fine particles (F) described above have preferably an average particle diameter of 30 to 500 nm, and at least one of copolymers constituting the above cross-linked fine particles (F) has preferably a glass transition temperature of 0° C. or lower.

A content of the cross-linked fine particles (F) described above is preferably 0.1 to 50 parts by mass based on total 100 parts by mass of the copolymer (A) and the phenol compound (a).

The photosensitive insulation resin composition described above further comprises preferably an adhesion auxiliary agent (E).

The cured product according to the present invention is prepared by curing the photosensitive insulation resin composition described above.

The semiconductor element according to the present invention has a cured insulation film formed by using the photosensitive insulation resin composition described above.

Using the photosensitive insulation resin composition according to the present invention makes it possible to form a cured product which is excellent in an insulation property, a heat impact resistance, an adhesive property and the like, and the above cured product is useful as a permanent film resist of an interlayer insulation film, a surface protecting layer and the like in a semiconductor element.

### BRIEF EXPLANATION OF THE DRAWINGS

FIG. 1 is a cross section of a base material for evaluating a heat impact resistance.

FIG. 2 is an upper surface drawing of the base material for evaluating a heat impact resistance.

FIG. 3 is an upper surface drawing of a base material for evaluating an electric insulation property.

FIG. 4 is a cross sectional schematic drawing of a semiconductor element.

FIG. 5 is a cross sectional schematic drawing of a semiconductor element.

### EXPLANATIONS OF CODES

1 Copper foil
2 Base material
3 Base material
11 Base material
12 metal pad
13, 16 Insulation film (cured film)
14 Metal wiring
15 Semiconductor element material

### BEST MODE FOR CARRYING OUT THE INVENTION

The photosensitive insulation resin composition according to the present invention and the cured product thereof shall specifically be explained below.

### Photosensitive Insulation Resin Composition:

The photosensitive insulation resin composition according to the present invention comprises (A) the copolymer comprising 10 to 99 mole % of the constitutional unit (A1) represented by Formula (1) described above and 90 to 1 mole % of the constitutional unit (A2) represented by Formula (2) described above (provided that the total of all constitutional units constituting the above copolymer (A) is 100 mole %), (B) the compound (B1) having an oxetanyl group, (C) the photosensitive acid generator, (D) the solvent and (F) the cross-linked fine particles. Also, the photosensitive insulation resin composition described above comprises preferably the compound (B2) having an epoxy group since it reduces generation of an outgas in curing to prevent voids from being produced and enhances more the adhesive property. Further, it can contain, if necessary, other additives such as the phenol compound (a), the adhesion auxiliary agent (E), a sensitizer, a leveling agent and the like.

### Copolymer (A):

The copolymer (A) used in the present invention is a copolymer which comprises the constitutional unit (A1) represented by Formula (1) described above and the constitutional unit (A2) represented by Formula (2) described above and which shows an alkali solubility.

The above copolymer (A) can be obtained, for example, by copolymerizing a monomer which can form the constitutional unit (A1) represented by Formula (1) with a monomer which can form the constitutional unit (A2) represented by Formula (2).

The monomer which can form the constitutional unit (A1) represented by Formula (1) described above includes a monomer represented by the following Formula (3):

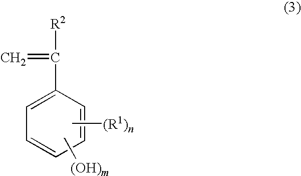

(wherein R¹ represents an alkyl group having 1 to 4 carbon atoms, an alkoxy group or an aryl group; R² represents a hydrogen atom or methyl; m is an integer of 1 to 3, and n is an integer of 0 to 3; and m+n≦5).

To be specific, it includes aromatic vinyl compounds having a phenolic hydroxyl group such as p-hydroxystyrene, m-hydroxystyrene, o-hydroxystyrene, p-isopropenylphenol, m-isopropenylphenol, o-isopropenylphenol and the like, and among them, p-hydroxystyrene and p-isopropenylphenol are preferably used.

The above monomers can be used alone or in combination of two or more kinds thereof.

Monomers obtained by blocking a hydroxyl group of the monomer represented by Formula (3) described above with, for example, a t-butyl group, an acetyl group and the like can be used as the monomer which can form the constitutional unit (A1). When the copolymerization is carried out by using the above monomers, a copolymer obtained is deblocked by a publicly known method, for example, under the presence of an acid catalyst to convert a protecting group such as a t-butyl group, an acetyl group and the like to a hydroxyl group, whereby the copolymer (A) having the constitutional unit (A1) can be obtained.

The monomer which can form the constitutional unit (A2) represented by Formula (2) described above includes a monomer represented by the following Formula (4):

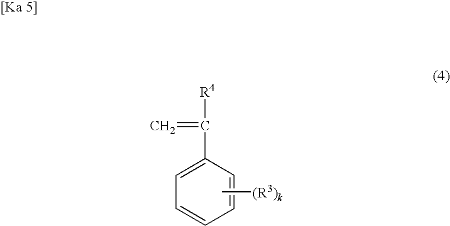

(wherein R³ represents an alkyl group having 1 to 4 carbon atoms, an alkoxy group or an aryl group; R⁴ represents a hydrogen atom or methyl; and k is an integer of 0 to 3).

To be specific, it includes aromatic vinyl compounds such as styrene, α-methylstyrene, o-methylstyrene, m-methylstyrene, p-methylstyrene, o-methoxystyrene, m-methoxystyrene, p-methoxystyrene and the like, and among them, styrene, α-methylstyrene and p-methoxystyrene are preferred. Styrene is particularly preferred.

The above monomers can be used alone or in combination of two or more kinds thereof.

In the present invention, the copolymer (A) preferably comprises substantially only the constitutional unit (A1) and the constitutional unit (A2) each described above since the cured product showing an excellent electric insulation property is obtained, and other monomers in addition to the monomer which can form the constitutional unit (A1) and the monomer which can form the constitutional unit (A2) can be copolymerized as long as the effects of the present invention are not damaged.

The above other monomers include, for example, compounds having an alicyclic skeleton, unsaturated carboxylic acids or acid anhydrides thereof, esters of unsaturated carboxylic acids, unsaturated nitrites, unsaturated amides, unsaturated imides, unsaturated alcohols and the like.

To be more specific, the compounds having an alicyclic skeleton include, for example, bicycle[2.2.1]hepto-2-ene (norbornene), tetracyclo[4.4.0.1^{2,5}. 1^{7,10}]dodeca-3-ene, cyclobutene, cyclopentene, cyclooctene, cyclopentadiene, tricyclo[5.2.1.0^{2,6}]decene and the like;

the unsaturated carboxylic acids include (meth)acrylic acid, maleic acid, fumaric acid, crotonic acid, mesaconic acid, citraconic acid, itaconic acid, maleic anhydride, citraconic anhydride and the like;
the esters of unsaturated carboxylic acids include methyl ester, ethyl ester, n-propyl ester, i-propyl ester, n-butyl ester, i-butyl ester, sec-butyl ester, t-butyl ester, n-amyl ester, n-hexyl ester, cyclohexyl ester, 2-hydroxyethyl ester, 2-hydroxypropyl ester, 3-hydroxypropyl ester, 2,2-dimethyl-3-hydroxypropyl ester, benzyl ester, isoboronyl ester, tricyclodecanyl ester and 1-adamantyl ester of the unsaturated carboxylic acids described above; the unsaturated nitrites include (meth)acrylonitrile, malonitrile, fumaronitrile, mesacononitrile, citracononitrile, itacononitrile and the like;
the unsaturated amides include (meth)acrylamide, crotonamide, maleinamide, fumaramide, mesaconamide, citraconamide, itaconamide and the like;
the unsaturated imides include maleimide, N-phenylmaleimide, N-cyclohexylmaleimide and the like;
the unsaturated alcohols include (meth)allyl alcohol and the like. Further, N-vinylaniline, N-vinylpyridines, N-vinyl-ε-caprolactam, N-vinylpyrrolidone, N-vinylimidazole, N-vinylcarbazole and the like are included therein as well.

The above monomers can be used alone or in combination of two or more kinds thereof.

In the copolymer (A) used in the present invention, assuming that the total of all constitutional units constituting the copolymer (A) is 100 mole %, the constitutional unit (A1) described above accounts for 10 to 99 mole %, preferably 20 to 97 mole %, more preferably 30 to 95 mole % and particularly preferably 70 to 95 mole %, and the constitutional unit (A2) described above accounts for 90 to 1 mole %, preferably 80 to 3 mole %, more preferably 70 to 5 mole % and particularly preferably 30 to 5 mole %. If the constitutional units (A1) and (A2) fall in the ranges described above, the good patterning characteristic (high resolution) is shown, and the cured product obtained shows a markedly excellent insulation property. When the other monomers are copolymerized, constitutional units derived from the other monomers account for 1 to 20 mole %, preferably 1 to 15 mole % assuming that the total of all constitutional units constituting the copolymer (A) is 100 mole %. In the above case, the constitutional unit (A1) described above accounts for 1 to 98 mole %, preferably 19 to 98 mole %, and the constitutional unit (A2) accounts for 90 to 1 mole %, preferably 80 to 1 mole %.

In the copolymer (A) described above, arrangement of the constitutional unit (A1) and the constitutional unit (A2) with the constitutional units formed from the other monomers shall not specifically be restricted, and the copolymer (A) may be either of a random copolymer and a block copolymer.

Assuming that the copolymer (A) is constituted from the constitutional units described above, that particularly the constitutional unit (A2) is the constitutional unit represented by Formula (2′) described above and that the contents of the respective constitutional units fall in the ranges described above, the cured product which is excellent in various characteristics such as a resolution, an electric insulation property, a heat impact property, an adhesive property and the like, particularly the cured product which is excellent in both of an electric insulation property and a heat impact property can be formed

A molecular weight of the copolymer (A) shall not specifically be restricted, and the weight average molecular weight (Mw) in terms of polystyrene which is measured by gel permeation chromatography (GPC) is, for example, 200,000 or less, preferably 2,000 to 200,000, more, preferably 2,000 to 15,000. A ratio (Mw/Mn) of the weight average molecular weight (Mw) to the number average molecular weight (Mn) is preferably 1.0 to 10.0, more preferably 1.0 to 8.0. If Mw is less than the lower limit described above, the cured product is reduced in physical properties such as a heat resistance, an elongation and the like in a certain case. If it exceeds the upper limit described above, the compatibility with the other components is reduced, and the patterning characteristic is reduced in a certain case. Also, if Mw/Mn exceeds the upper limit described above, the cured product is reduced in a heat resistance, a compatibility with the other components and a patterning characteristic in a certain case. Mn and Mw were measured by using GPC columns (G2000HXL: 2 columns and G3000HXL: 1 column) manufactured by Tosoh Corp. on the analytical conditions of a flow amount of 1.0 ml/minute, an eluting solvent of tetrahydrofuran and a column temperature of 40° C. by means of a differential refractometer using monodispersed polystyrene as a standard material.

The copolymer (A) described above can be obtained by polymerizing the monomer which can form the constitutional unit (A1) or the monomer in which a hydroxyl group is blocked with the monomer which can form the constitutional unit (A2) and, if necessary, the other monomers in a solvent under the presence of an initiator. The polymerizing method shall not specifically be restricted, and radical polymerization or anionic polymerization is suitably used in order to obtain the copolymer having a molecular weight falling in the range described above.

Usually, a monomer in which a hydroxyl group is blocked is used as the monomer which can form the constitutional unit (A1). When the monomer in which a hydroxyl group is blocked is used, it is deblocked by reacting at a temperature of 50 to 150° C. for 1 to 30 hours in a solvent under the presence of an acid catalyst such as hydrochloric acid, sulfuric acid and the like after polymerization, whereby the constitutional unit in which a hydroxyl group is blocked is converted to the constitutional unit (A2) containing a phenolic hydroxyl group.

In the photosensitive insulation resin composition according to the present invention, the copolymer (A) accounts for usually 5 to 60% by mass, preferably 10 to 50% by mass based on the whole resin composition (including the solvent (D)). If an amount of the copolymer (A) falls in the range described above, a handling property of the composition is good, and the cured product can readily be formed.

### Phenol Compound (a):

In the photosensitive insulation resin composition according to the present invention, a compound (hereinafter referred to as “the phenol compound (a)”) having a phenolic hydroxyl group other than the copolymer (A) described above can be used in combination when the copolymer (A) has an unsatisfactory alkali solubility.

The phenol compound (a) described above includes resins (hereinafter referred to as “the phenol resin”) having a phenolic hydroxyl group other than the copolymer (A), low molecular compounds (hereinafter referred to as “the phenolic hydroxyl group-containing low molecular compound”) having a phenolic hydroxyl group and the like.

The phenol resin described above includes phenol/formaldehyde condensation novolac resins, cresol/formaldehyde condensation novolac resins, phenol-naphthol/formaldehyde condensation novolac resins, hydrostyrene homopolymers and the like.

The phenolic hydroxyl group-containing low molecular compound described above includes 4,4′-dihydroxydiphenylmethane, 4,4′-dihydroxydiphenyl ether, tris(4-hydroxydiphenyl)methane, 1,1-bis(4-hydroxydiphenyl)-1-phenylethane, tris(4-hydroxydiphenyl)ethane, 1,3-bis[1-(4-hydroxydiphenyl)-1-methylethyl]benzene, 1,4-bis[1-(4-hydroxydiphenyl)-1-methylethyl]benzene, 4,6-bis[1-(4-hydroxydiphenyl)-1-methylethyl]-1,3-dihydroxybenzene, 1,1-bis(4-hydroxydiphenyl)-1-[4-{1-(4-hydroxydiphenyl)-1-methylethyl}phenyl]ethane, 1,1,2,2-tetra(4-hydroxydiphenyl)ethane and the like.

The phenol resin and the phenolic hydroxyl group-containing low molecular compound described above may be used in combination, but usually either of them is used. In the photosensitive insulation resin composition of the present invention, an amount of the phenol compound (a) is preferably 1 to 200 parts by mass, more preferably 5 to 100 parts by mass and most preferably 10 to 50 parts by mass based on 100 parts by mass of the copolymer (A) described above. The resin composition containing the phenol compound (a) in the range described above can exhibit a satisfactory alkali solubility.

In the photosensitive insulation resin composition of the present invention, a total amount of the copolymer (A) and the phenol compound (a) is usually 40 to 95 parts by mass, preferably 50 to 80 parts by mass based on total 100 parts by mass of the components other than the solvent (D) in the composition.

### Cross-Linking Agent (B):

The compound (B1) having an oxetanyl group used in the present invention and the compound (B2) having an epoxy group used if necessary (hereinafter they shall be collectively referred to as “the cross-linking agent (B)”) act as a cross-linking component which reacts with the copolymer (A) and the phenol compound (a) described above.

The compound (B1) having an oxetanyl group (hereinafter referred to as “the oxetanyl group-containing compound (B1)”) has at least one oxetanyl group in a molecule. To be specific, compounds represented by the following Formulas (A) to (C) can be listed:

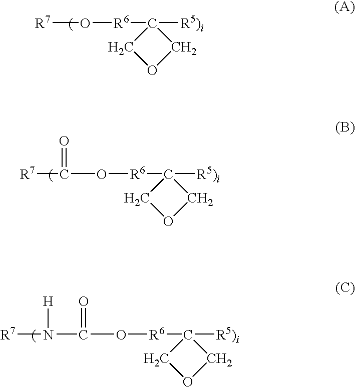

(in Formulas (A), (B) and (C), R⁵ represents an alkyl group such as methyl, ethyl, propyl and the like; R⁶ represents an alkylene group such as methylene, ethylene, propylene and the like; R⁷ represents an alkyl group such as methyl, ethyl, propyl, hexyl and the like; an aryl group such as phenyl, xylyl and the like; a dimethylsiloxane residue represented by the following Formula (i); an alkylene group such as methylene, ethylene, propylene and the like; phenylene; or a group represented by the following Formulas (ii) to (vi), and i is equivalent to a valence of R⁷ and is an integer of 1 to 4):

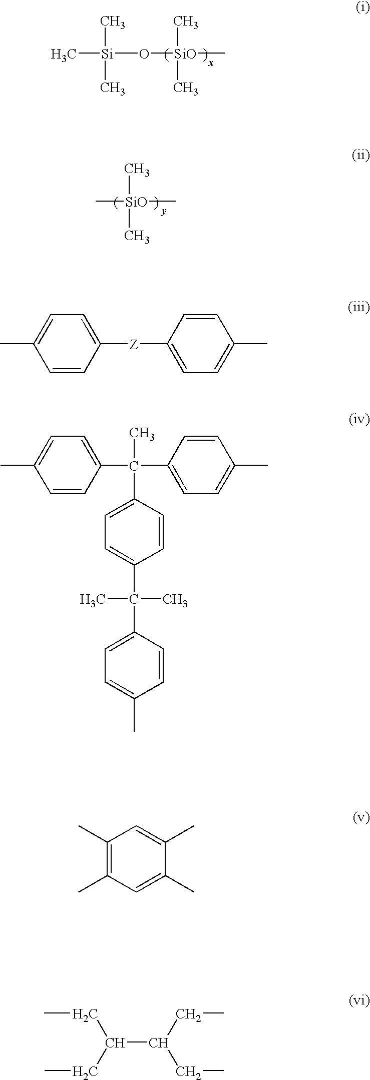

(wherein x and y are an integer of 0 to 50, and Z is a single bond or a divalent group represented by —CH₂—, —C(CH₃)₂—, —C(CF₃)₂— or —SO₂—).

The compounds represented by Formulas (A) to (C) described above include bis[(3-ethyl-3-oxetanylmethoxy)methyl]benzene (trade name: XDO, manufactured by Toagosei Co., Ltd.), bis[(3-ethyl-3-oxetanylmethoxy)methyl-phenyl]methane, bis[(3-ethyl-3-oxetanylmethoxy)methyl-phenyl]ether, bis[(3-ethyl-3-oxetanylmethoxy)methyl-phenyl]propane, bis[(3-ethyl-3-oxetanylmethoxy)methyl-phenyl]sulfone, bis[(3-ethyl-3-oxetanylmethoxy)methyl-phenyl]ketone, bis[(3-ethyl-3-oxetanylmethoxy)methyl-phenyl]hexafluoropropane, tri[(3-ethyl-3-oxetanylmethoxy)methyl]benzene, tetra[(3-ethyl-3-oxetanylmethoxy)methyl]benzene and compounds represented by the following Formulas (D) to (H):

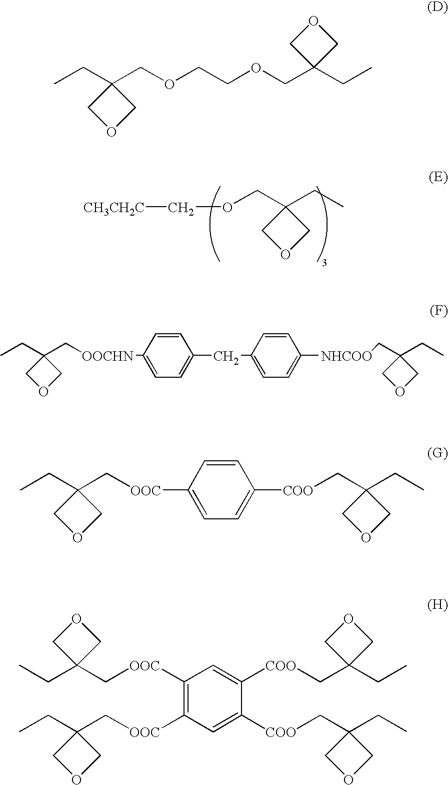

In addition to the above compounds, a compound having a polyvalent oxetane ring having a high molecular weight can be used as well. To be specific, it includes, for example, an oxetane oligomer (trade name: Oligo-OXT, manufactured by Toagosei Co., Ltd.) and compounds represented by the following Formulas (1) to (K):

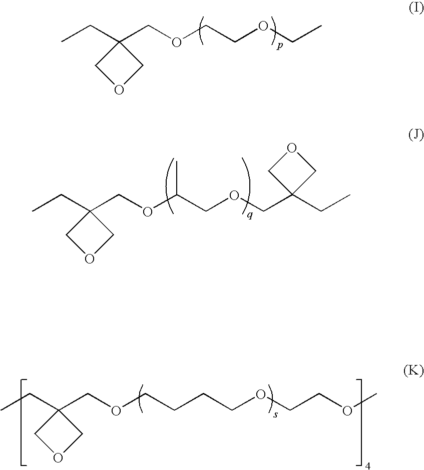

(wherein p, q and s each are independently an integer of 0 to 10,000).

Among the compounds described above, preferred are 1,4-bis{[(3-ethyloxetane-3-yl)methoxy]methyl}benzene (trade name: OXT-121, manufactured by Toagosei Co., Ltd.) and 3-ethyl-3-{[(3-ethyloxetane-3-yl)methoxy]methyl}oxetane (trade name: OXT-221, manufactured by Toagosei Co., Ltd.).

The compound (B2) having an epoxy group (hereinafter referred to as “the epoxy group-containing compound (B2)”) shall not specifically be restricted as long as it is a compound having an epoxy group in a molecule, and it includes, to be specific, phenol novolac type epoxy resins, cresol novolac type epoxy resins, bisphenol A type epoxy resins, trisphenol type epoxy resins, tetraphenol type epoxy resins, phenol-xylylene type epoxy resins, naphthol-xylylene type epoxy resins, phenol-naphthol type epoxy resins, phenol-dicyclopentadiene type epoxy resins, alicyclic epoxy resins, aromatic epoxy resins, aliphatic epoxy resins, epoxycyclohexene resins and the like.

The phenol novolac type epoxy resins described above include Epikote 152 and 154 (trade names) manufactured by Japan Epoxy Resins Co., Ltd.; the cresol novolac type epoxy resins described above include an EOCN series (trade names) manufactured by Nippon Kayaku Co., Ltd.; the bisphenol type epoxy resins described above include an NC3000 series (trade names) manufactured by Nippon Kayaku Co., Ltd.; the trisphenol type epoxy resins described above include an EPPN series (trade names) manufactured by Nippon Kayaku Co., Ltd.; the phenol-naphthol type epoxy resins described above include an NC7000 series (trade names) manufactured by Nippon Kayaku Co., Ltd.; the phenol-dicyclopentadiene type epoxy resins described above include an XD1000 series (trade names) manufactured by Nippon Kayaku Co., Ltd.; the bisphenol A type epoxy resins described above include an Epikote 801 series (trade names) manufactured by Japan Epoxy Resins Co., Ltd.; the aliphatic epoxy resins described above include pentaerythritol glycidyl ether (trade name: Denacol EX411, manufactured by Nagase ChemteX Corporation), trimethylolpropane polyglycidyl ether (trade name: Denacol EX321, 321L, manufactured by Nagase ChemteX Corporation), glycerol polyglycidyl ether (trade name: Denacol EX313, EX314, manufactured by Nagase ChemteX Corporation), neopentyl glycol diglycidyl ether (trade name: Denacol EX211, manufactured by Nagase ChemteX Corporation), ethylene/polyethylene glycol diglycidyl ether (trade name: Denacol EX810, 850 series, manufactured by Nagase ChemteX Corporation), propylene/polypropylene glycol diglycidyl ether (trade name: Denacol EX911, 941, 920 series, manufactured by Nagase ChemteX Corporation), 1,6-hexanediol diglycidyl ether (trade name: Denacol EX212, manufactured by Nagase ChemteX Corporation), sorbitol polyglycidyl ether (trade name: Denacol EX611, EX612, EX614, EX614B, EX610U, manufactured by Nagase ChemteX Corporation), propylene glycol diglycidyl ether (trade name: Epolite 70P, manufactured by Kyoeisha Chemical Co., Ltd.) and trimethylolpropane triglycidyl ether (trade name: Epolite 100MF, manufactured by Kyoeisha Chemical Co., Ltd.); the aromatic epoxy resins described above include phenyl glycidyl ether (trade name: Denacol EX141, manufactured by Nagase ChemteX Corporation) and resorcinol diglycidyl ether (trade name: Denacol EX201, manufactured by Nagase ChemteX Corporation); the epoxycyclohexene resins include 3,4-epoxycyclohexenylmethyl-3′,4′-epoxycyclohexene carboxylate (trade name: Celloxide 2021, 2021A, 2021P, manufactured by Daicel Chemical Industries Co., Ltd.), 1,2:8,9-diepoxylimonen (trade name: Celloxide 3000, manufactured by Daicel Chemical Industries Co., Ltd.), 1,2-epoxy-4-(2-oxiranyl)cyclohexane adduct of 2,2-bis(hydroxymethyl)-1-butanol and 3,4-epoxycyclohexenylmethyl-3′,4′-epoxycyclohexene carboxylate (trade name: EHPE3150CE, manufactured by Daicel Chemical Industries Co., Ltd.) and the like.

Among them, preferred are the phenol novolac type epoxy resins (trade names: Epikote 152 and 154, manufactured by Japan Epoxy Resins Co., Ltd.), the bisphenol A type epoxy resins (trade names: Epikote 801 series, manufactured by Japan Epoxy Resins Co., Ltd.), resorcinol diglycidyl ether (trade name: Denacol EX201, manufactured by Nagase ChemteX Corporation), pentaerythritol glycidyl ether (trade name: Denacol EX411, manufactured by Nagase ChemteX Corporation), trimethylolpropane polyglycidyl ether (trade name: Denacol EX321, 321L, manufactured by Nagase ChemteX Corporation), glycerol polyglycidyl ether (trade name: Denacol EX313, EX314, manufactured by Nagase ChemteX Corporation), phenyl glycidyl ether (trade name: Denacol EX141, manufactured by Nagase ChemteX Corporation), neopentyl glycol diglycidyl ether (trade name: Denacol EX211, manufactured by Nagase ChemteX Corporation), ethylene/polyethylene glycol diglycidyl ether (trade name: Denacol EX810, 850 series, manufactured by Nagase ChemteX Corporation), propylene/polypropylene glycol diglycidyl ether (trade name: Denacol EX911, 941, 920 series, manufactured by Nagase ChemteX Corporation), 1,6-hexanediol diglycidyl ether (trade name: Denacol EX212, manufactured by Nagase ChemteX Corporation), sorbitol polyglycidyl ether (trade name: Denacol EX611, EX612, EX614, EX614B, EX610U, manufactured by Nagase ChemteX Corporation), propylene glycol diglycidyl ether (trade name: Epolite 70P, manufactured by Kyoeisha Chemical Co., Ltd.) and trimethylolpropane triglycidyl ether (trade name: Epolite 100 MF, manufactured by Kyoeisha Chemical Co., Ltd.).

The above cross-linking agents (B) can be used alone or in combination of two or more kinds thereof. A blending amount of the above cross-linking agents (B) in the present invention is preferably 1 to 100 parts by mass, more preferably 2 to 70 parts by mass based on total amount 100 parts by mass of the copolymer (A) and the phenol compound (a) described above. If the blending amount falls in the range described above, a cured film obtained has a satisfactory chemical resistance and a high resolution. When the compound (B1) having an oxetanyl group and the compound (B2) having an epoxy group are used in combination, assuming that an amount of the above cross-linking agents (B) contained in the photosensitive insulation resin composition of the present invention is 100 parts by mass, a blending amount of the compound (B1) having an oxetanyl group is usually 10 to 90 parts by mass, preferably 25 to 75 parts by mass and more preferably 40 to 60 parts by mass, and a blending amount of the compound (B2) having an epoxy group is usually 90 to 10 parts by mass, preferably 75 to 25 parts by mass and more preferably 60 to 40 parts by mass. If a content ratio of the compound (B1) having an oxetanyl group to the compound (B2) having an epoxy group falls in the range described above, it is preferred in terms of the sensitivity.

### Photosensitive Acid Generator (C):

The photosensitive acid generator (C) (hereinafter referred to as “the acid generator (C)”) used in the present invention is a compound generating acid by irradiation with a radial ray and the like. An alkyl ether group or an epoxy group in the cross-linking agent (B) is reacted with the copolymer (A) and the phenol compound (a) described above by a catalytic action of the acid generated, and the resin composition is cured, whereby a negative type pattern can be formed.

The acid generator (C) shall not specifically be restricted as long as it is a compound generating acid by irradiation with a radial ray and the like, and it includes, for example, onium salt compounds, halogen-containing compounds, diazoketone compounds, sulfone compounds, sulfonic acid compounds, sulfonimide compounds, diazomethane compounds and the like.

### Onium Salt Compounds:

The onium salt compounds include, for example, iodonium salts, sulfonium salts, phosphonium salts, diazonium salts, pyridinium salts and the like. The specific examples of the preferred onium salts include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-butylphenyl.diphenylsulfonium trifluoromethanesulfonate, 4-t-butylphenyl.diphenylsulfonium p-toluenesulfonate, 4,7-di-n-butoxynaphthyltetrahydrothiophenium trifluoromethanesulfonate, 4-(phenylthio)phenyldiphenylsulfonium tris(pentafluoroethyl)trifluorophosphate, 4-(phenylthio)phenyldiphenylsulfonium tris(heptafluoropropyl)trifluorophosphate, di-p-tolyliodonium tris(hexafluoroethyl)trifluorophosphate, 4-(phenylthio)phenyldiphenylsulfonium hexafluoroantimonate and the like.

### Halogen-Containing Compounds:

The halogen-containing compounds include, for example, haloalkyl group-containing hydrocarbon compounds, haloalkyl group-containing heterocyclic compounds and the like. The specific examples of the preferred halogen-containing compounds include 1,10-dibromo-n-decane, 1,1-bis(4-chlrophenyl)-2,2,2-trichloroethane and s-triazine derivatives such as phenyl-bis(trichloromethyl)-s-triazine, 4-methoxyphenyl-bis(trichloromethyl)-s-triazine, styryl-bis(trichloromethyl)-s-triazine, naphthyl-bis(trichloromethyl)-s-triazine, 2-[2-(5-methylfuran-2-yl)ethenyl]-4,6-bis(trichloromethyl)-s-triazine and the like.

### Diazoketone Compounds:

The diazoketone compounds include, for example, 1,3-diketo-2-diazo compounds, diazobenzoquinone compounds, diazonaphthoquinone compounds and the like, and the specific examples thereof include 1,2-naphthoquinonediazide-4-sulfonic ester compounds of phenols.

### Sulfone Compounds:

The sulfone compounds include, for example, β-ketosulfone compounds, β-sulfonylsulfone compounds and α-diazo compounds of the above compounds, and the specific examples thereof include mesitylphenacylsulfone, bis(phenacylsulfonyl)methane and the like.

### Sulfonic Acid Compounds:

The sulfonic acid compounds include, for example, alkyl sulfonates, haloalkyl sulfonates, aryl sulfonates, iminosulfonates and the like. The preferred specific examples thereof include benzoin tosylate, pyrogallol tristrifluoromethanesulfonate, o-nitrobenzyl trifluoromethanesulfonate, o-nitrobenzyl p-toluenesulfonate and the like.

### Sulfonimide Compounds:

The specific examples of the sulfonimide compounds include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicycle[2.2.1]hepro-5-ene-2,3-dicarboxylmide, N-(trifluoromethylsulfonyloxy)naphthylimide and the like.

### Diazomethane Compounds:

The specific examples of the diazomethane compounds include bis(trifluoromethylsulfonyl)diazomethane,

bis(cyclohexylsulfonyl)diazomethane, bis(phenylsulfonyl)diazomethane and the like.

In the present invention, the above acid generator (C) may be used alone or in combination of two or more kinds thereof. A blending amount of the acid generator (C) is preferably 0.1 to 10 parts by mass, more preferably 0.3 to 5 parts by mass based on total amount 100 parts by mass of the copolymer (A) and the phenol compound (a) described above from the viewpoint that a resolution, a pattern form and the like of the photosensitive insulation resin composition according to the present invention are secured. If the blending amount falls in the range described above, the composition is sufficiently cured, and the cure product is improved in a heat resistance. In addition thereto, it is provided with a good transparency to a radial ray and less liable to cause degradation of a pattern form.

### Solvent (D):

The solvent (D) used in the present invention is added in order to enhance of a handling property of the resin composition and control a viscosity and a storage stability thereof. The solvent (D) shall not specifically be restricted and includes, for example, organic solvents including:

ethylene glycol monoalkyl ether acetates such as ethylene glycol monomethyl ether acetate, ethylene glycol monoethyl ether acetate and the like;
propylene glycol monoalkyl ethers such as propylene glycol monomethyl ether, propylene glycol monoethyl ether, propylene glycol monopropyl ether, propylene glycol monobutyl ether and the like;
propylene glycol dialkyl ethers such as propylene glycol dimethyl ether, propylene glycol diethyl ether, propylene glycol dipropyl ether, propylene glycol dibutyl ether and the like;
propylene glycol monoalkyl ether acetates such as propylene glycol monomethyl ether acetate, propylene glycol monoethyl ether acetate, propylene glycol monopropyl ether acetate, propylene glycol monobutyl ether acetate and the like; cellosolves such as ethyl cellosolve, butyl cellosolve and the like;
carbitols such as butyl carbitol and the like; lactic esters such as methyl lactate, ethyl lactate, n-propyl lactate, isopropyl lactate and the like;
aliphatic carboxylic esters such as ethyl acetate, n-propyl acetate, isopropyl acetate, n-butyl acetate, isobutyl acetate, n-amyl acetate, isoamyl acetate, isopropyl propionate, n-butyl propionate, isobutyl propionate and the like;
other esters such as methyl 3-methoxypropionate, ethyl 3-methoxypropionate, methyl 3-ethoxypropionate, ethyl 3-ethoxypropionate, methyl pyruvate, ethyl pyruvate and the like;
aromatic hydrocarbons such as toluene, xylene and the like; ketones such as 2-heptanone, 3-heptanone, 4-heptanone, cyclohexanone and the like;
amides such as N-dimethylformamide, N-methylacetamide, N,N-dimethylacetamide, N-methylpyrrolidone and the like; lactones such as γ-butyrolactone and the like. The above organic solvents can be used alone or in a mixture of two or more kinds thereof.

An amount of the solvent (D) in the present invention shall not specifically be restricted as long as it is suitably selected according to the uses of the composition and the coating method and can leave the composition staying in an even state, and it is usually 10 to 80 parts by mass, preferably 30 to 75 parts by mass and more preferably 40 to 70 parts by mass based on the whole composition.

### Adhesion Auxiliary Agent (E):

The adhesion auxiliary agent (E) used in the present invention is preferably a functional silane coupling agent and includes, for example, silane coupling agents having a reactive substituent such as a carboxyl group, a methacryloyl group, an isocyanate group, an epoxy group and the like. To be specific, it includes trimethoxysilyl benzoate, γ-methacryloxypropyltrimethoxysilane, vinyltriacetoxysilane, vinyltrimethoxysilane, γ-isocyanatepropyltrimethoxysilane, γ-glycidoxypropyltrimethoxysilane, β-(3,4-epoxycyclohexyl)ethyltrimethoxysilane, 1,3,5-N-tris(trimethoxysilyl) isocyanurate and the like.

### Cross-Linked Fine Particle (F):

In the cross-linking fine particle (F) (hereinafter referred to as “the cross-linked fine particle (F)”) used in the present invention, at least one of the glass transition temperatures (Tg) of the copolymers constituting the cross-linked fine particle is preferably 0° C. or lower, and preferred is, for example, a copolymer of a cross-linking monomer having two or more unsaturated polymerizable groups (hereinafter referred to as “the cross-linking monomer”) with one or more other monomers (hereinafter referred to as “the other monomers (f)”) which are polymerizable with the above cross-linking monomer and which are selected so that at least one of Tg of the copolymers constituting the cross-linked fine particle (F) is preferably 0° C. or lower. The other monomers (f) described above are preferably monomers having a functional group such as, for example, a carboxyl group, an epoxy group, an amino group, an isocyanate group, a hydroxyl group and the like as a functional group other than the polymerizable group.

Tg of the copolymers constituting the cross-linked fine particle (F) is a value obtained by solidifying and drying a dispersion of the cross-linked fine particles and then measuring it in a range of −100 to 150° C. at a heating speed of 10° C./minute by means of DSC of SSC/5200H manufactured by Seiko Instruments Inc.

The cross-linking monomer described above includes compounds having plural polymerizable unsaturated groups such as divinylbenzene, diallyl phthalate, ethylene glycol di(meth)acrylate, propylene glycol di(meth)acrylate, trimethylolpropane tri(meth)acrylate, pentaerythritol tri(meth)acrylate, polyethylene glycol di(meth)acrylate, polypropylene glycol di(meth)acrylate and the like. Among them, divinylbenzene is preferred.

Capable of being shown as the examples of the other monomers (f) described above are diene compounds such as butadiene, isoprene, dimethylbutadiene, chloroprene, 1,3-pentadiene and the like;

unsaturated nitrile compounds such as (meth)acrylonitrile, α-chloroacrylonitrile, α-chloromethylacrylonitrile, α-methoxyacrylonitrile, α-ethoxyacrylonitrile, crotononitrile, cinnamonitrile, itaconodinitrile, malodinitrile, fumarodinitrile and the like;
unsaturated amides such as (meth)acrylamide, N,N′-methylenebis(meth)acrylamide, N,N′-ethylenebis(meth)acrylamide, N,N′-hexamethylenebis(meth)acrylamide, N-hydroxymethyl(meth)acrylamide, N-(2-hydroxyethyl)(meth)acrylamide, N,N-bis(2-hydroxyethyl)(meth)acrylamide, crotonamide, cinnamamide and the like;
(meth)acrylic esters such as methyl (meth)acrylate, ethyl (meth)acrylate, propyl (meth)acrylate, butyl (meth)acrylate, hexyl (meth)acrylate, lauryl (meth)acrylate, polyethylene glycol (meth)acrylate, polypropylene glycol (meth)acrylate and the like;
aromatic vinyl compounds such as styrene, α-methylstyrene, O-methoxystyrene, p-hydroxystyrene, p-isopropenylphenol and the like;
epoxy(meth)acrylates obtained by reacting diglycidyl ethers of bisphenol A, diglycidyl ethers of glycols and the like with (meth)acrylic acid, hydroxyalkyl (meth)acrylates and the like;
urethane(meth)acrylates obtained by reacting hydroxyalkyl (meth)acrylates with polyisocyanates;
epoxy group-containing unsaturated compounds such as glycidyl (meth)acrylate, (meth)acryl glycidyl ether and the like; unsaturated acid compounds such as (meth)acrylic acid, itaconic acid, β-(meth)acryloxyethyl succinate, β-(meth)acryloxyethyl maleate, β-(meth)acryloxyethyl phthalate, β-(meth)acryloxyethyl hexahydrophthalate and the like; amino group-containing unsaturated compounds such as dimethyl amino(meth)acrylate, diethyl amino(meth)acrylate and the like;
amide group-containing unsaturated compounds such as (meth)acrylamide, dimethyl(meth)acrylamide and the like; and hydroxyl group-containing unsaturated compounds such as hydroxyethyl (meth)acrylate, hydroxypropyl (meth)acrylate, hydroxybutyl (meth)acrylate and the like.

Among them, preferred are butadiene, isoprene, (meth)acrylonitrile, (meth)acrylic acid alkyl esters, styrene, p-hydroxystyrene, p-isopropenylphenol, glycidyl (meth)acrylate, (meth)acrylic acid, hydroxyalkyl (meth)acrylates and the like, and butadiene is particularly preferred.

Further, among them, at least one of the diene compounds such as butadiene and the like, at least one of the hydroxyl group-containing unsaturated compounds and at least one of the unsaturated acid compounds are particularly preferably used. To be specific, butadiene is preferably used as the diene compound; hydroxybutyl (meth)acrylate is preferably used as the hydroxyl group-containing unsaturated compounds; and (meth)acrylic acid is preferably used as the unsaturated acid compound.

A proportion of the cross-linking monomer to the other monomer (f) which constitute the cross-linked fine particles (F) described above is 1 to 20% by mass for the cross-linking monomer and 80 to 99% by mass for the other monomer (f), preferably 2 to 10% by mass for the cross-linking monomer and 90 to 98% by mass for the other monomer (f) based on the whole monomers used for the copolymerization. In particular, use of the diene compound as the other monomer (f), particularly butadiene in a proportion of preferably 20 to 80% by mass, more preferably 30 to 70% by mass based on the whole monomers used for the copolymerization makes it possible to provide the rubber-like, soft cross-linked fine particles, prevent cracks from being produced on the cured film obtained and provide the cured film having an excellent durability. Also, combined use of styrene and butadiene as the other monomer (f) makes it possible to provide the cured film having a low dielectric constant. When using the hydroxyl group-containing unsaturated compounds, a content thereof is preferably 1 to 79% by mass, more preferably 5 to 68% by mass based on 100% by mass of the whole monomers used for the copolymerization. If the hydroxyl group-containing unsaturated compounds are copolymerized in a content falling in the range described above, the polarity can be changed, and therefore the compatibility with various resins can be enhanced. This allows the cross-linked fine particles to be dispersed evenly in the system, and therefore an insulating film which is excellent in an insulation property and a crack resistance can be obtained. When using the unsaturated acid compounds, a content thereof is preferably 1 to 20% by mass, more preferably 2 to 10% by mass based on 100% by mass of the whole monomers used for the copolymerization. If the unsaturated acid compounds are copolymerized in a content falling in the range described above, a photosensitive insulating film having an excellent resolution can be obtained since the above compounds have an acid group and therefore have a high solubility or a high dispersibility in an alkali.

The cross-linked fine particles (F) described above have an average particle diameter of usually 30 to 500 nm, preferably 40 to 200 nm and more preferably 50 to 120 nm. A method for controlling a particle diameter of the cross-linked fine particles shall not specifically be restricted, and when the cross-linked fine particles are synthesized by emulsion polymerization, a method in which the number of micelles during emulsion polymerization is controlled by an amount of an emulsifier used to control the particle diameter can be shown as the example thereof. The average particle diameter described above is a value obtained by diluting a dispersion of the cross-linked fine particles according to an ordinary method and measuring it by means of a light scattering flow distribution measuring equipment LLPA-3000 manufactured by Otsuka Electronics Co., Ltd.

A blending amount of the cross-linked fine particles (F) is preferably 0.1 to 50 parts by mass, more preferably 1 to 20 parts by mass based on total 100 parts by mass of the copolymer (A) and the phenol compound (a) described above. If the blending amount falls in the range described above, the cured film obtained is provided with a heat impact resistance and a heat resistance and shows a good compatibility (dispersibility) with the other components.

### Other Additives:

Various additives such as a sensitizer, a leveling agent, other acid generators and the like can be added to the photosensitive insulation resin composition according to the present invention as long as the characteristics of the composition described above are not damaged.

On the other hand, a liquid rubber is added to conventional radial ray-sensitive insulation resin compositions in a certain case for the purpose of enhancing an adhesive property, and the above liquid rubber added has tended to reduce the resolution. Such liquid rubber means in many cases that it has a fluidity at room temperature, and known are, for example, acryl rubber (ACM), acrylonitrile-butadiene rubber (NBR), acrylonitrile-acrylate-butadiene rubber (NBA) and the like. The radial ray-sensitive insulation resin composition of the present invention is characterized by containing fundamentally no liquid rubber described above.

### Preparing Method for the Composition:

A preparing method for the photosensitive insulation resin composition of the present invention shall not specifically be restricted, and conventional preparing methods can be applied. Also, it can be prepared as well by putting the respective components into a sample bottle, stoppering it completely and then stirring it on a wave rotor.

### Cured Product:

The cured product obtained by curing the photosensitive insulation resin composition according to the present invention is excellent in an electrical insulation property, a heat impact resistance, an adhesive property and the like. Accordingly, the photosensitive insulation resin composition of the present invention can suitably be used particularly as a material for a surface protecting film, an interlayer insulating film and the like in semiconductor elements.

The cured product (cured film) according to the present invention can be formed, for example, in the following manner.

The photosensitive insulation resin composition described above is coated, for example, on a support such as a copper foil provided thereon with a resin, a copper-clad laminated board, a silicon wafer provided thereon with a metal-sputtered film, an aluminum substrate and the like, and the solvent is volatilized by drying to form a coating film. Then, it is exposed to light via a desired mask pattern and subjected to heat treatment (hereinafter this heat treatment shall be referred to as “PEB”), whereby reaction of the copolymer (A) and the phenol compound (a) with the cross-linking agent (B) is accelerated.

Next, it is developed in an alkaline developing liquid to dissolve and remove an unexposed part, whereby a desired pattern can be obtained. Then, it is further subjected to heat treatment, whereby a cured film having an insulation film characteristic can be obtained.

In this connection, coating methods such as, for example, a dipping method, a spraying method, a bar coating method, a roll coating method and a spin coating method and the like can be used as a method for coating the resin composition on the support. Also, the coated thickness can suitably be controlled by adjusting a coating means and a solid concentration and a viscosity of the composition.

A radial ray used for the exposure includes, for example, a UV ray, an electron beam, a laser beam and the like which are radiated from a low pressure mercury lamp, a high pressure mercury lamp, a metal halide lamp, a g ray stepper, an i ray stepper and the like. The exposure is suitably selected according to a light source used, a resin film thickness and the like, and when a UV ray is radiated from a high pressure mercury lamp, it is 1,000 to 50,000 J/m² assuming that the resin film thickness is 10 to 50 μm.

PEB treatment conditions after exposure are varied according to a blending amount of the resin composition, the film thickness used and the like, and the conditions are usually 70 to 150° C., preferably 80 to 120° C. and 1 to 60 minutes.

A developing method carried out in an alkaline developing liquid includes a shower developing method, a spray developing method, a dipping developing method, a puddle developing method and the like, and the developing conditions are usually 20 to 40° C. and 1 to 10 minutes.

The alkaline developing liquid described above includes, for example, alkaline aqueous solutions prepared by dissolving alkaline compounds such as sodium hydroxide, potassium hydroxide, aqueous ammonia, tetramethylammonium hydroxide, choline and the like in water and controlling a concentration thereof so that it is 1 to 10% by mass. A water-soluble organic solvent such as, for example, methanol and ethanol, a surfactant and the like can be added as well in suited amounts to the alkaline aqueous solution described above. After developed in the alkaline developing liquid, the patterned coating film is washed with water and dried.

The heat treatment conditions after the development shall not specifically be restricted, and the heat treatment is carried out at a temperature of 50 to 200° C. for 30 minutes to 10 hours according to the uses of the cured product, whereby the patterned coating film can be cured. The above heat treatment after the development may be carried out in the steps of two or more stages in order to sufficiently promote curing of the pattern-like coating film and prevent it from being deformed. For example, the coating film is heated at a temperature of 50 to 120° C. for 5 minutes to 2 hours at the first stage, and it is heated at a temperature of 80 to 200° C. for 10 minutes to 10 hours at the second stage, whereby the pattern-like coating film can be cured. In the above curing conditions, a hot plate, an oven, an infrared furnace and the like can be used as a heating facility.

The cured product according to the present invention is excellent in an electrical insulation property and has a resistance value of preferably 10⁸Ω or more, more preferably 10⁹Ω or more and further f preferably 10¹⁰Ω or more after a migration test thereof. In this regard, the migration test described above is a test carried out, to be specific, in the following manner.

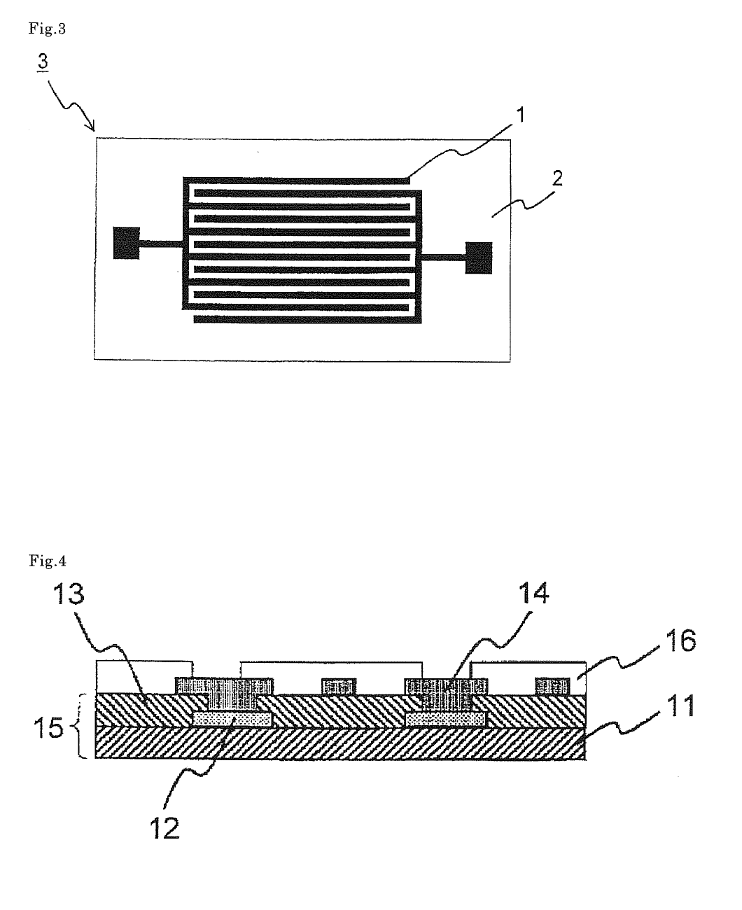

The resin composition is coated on an evaluation substrate shown in FIG. 3 and heated at 110° C. for 3 minutes by means of a hot plate to prepare a resin coating film having a thickness of 10 μm on a copper foil. Then, the resin coating film is heated at 190° C. for one hour by means of a convection oven and cured to obtain a cured film. The above evaluation substrate provided thereon with the cured film is put in a migration evaluation system (AEI, EHS-221MD, manufactured by Tabai Espec Corp.) and treated for 200 hours on the conditions of a temperature of 121° C., a humidity of 85%, a pressure of 1.2 atmosphere and an applied voltage of 5 V, and then a resistance value (Ω) of the evaluation substrate is measured.

The cured product according to the present invention is excellent in a heat impact resistance, and a cycle number for producing cracks on the cured product in a thermal shock test in which −65° C./30 minutes to 150° C./30 minutes is one cycle is preferably 1000 cycles or more, more preferably 1500 cycles or more and further preferably 2000 cycles or more. In this regard, the thermal shock test described above is a test carried out, to be specific, in the following manner.

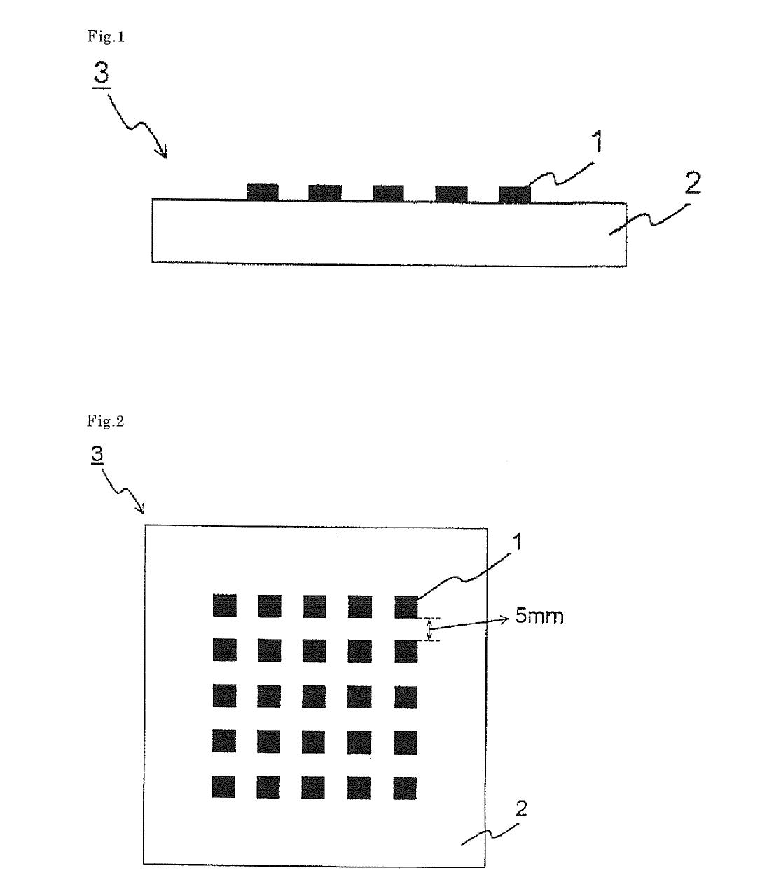

The resin composition is coated on an evaluation substrate shown in FIG. 1 and FIG. 2 and heated at 110° C. for 3 minutes by means of a hot plate to prepare a resin coating film having a thickness of 10 μm on a copper foil. Then, the resin coating film is heated at 190° C. for one hour by means of a convection oven and cured to obtain a cured film. The above evaluation substrate provided thereon with the cured film is subjected to a tolerant test in which −65° C./30 minutes to 150° C./30 minutes is one cycle by means of a thermal shock test device (TSA-40L, manufactured by Tabai Espec Corp.). A cycle number in which defaults such as cracks are generated on the cured film is confirmed every 100 cycles. Accordingly, the larger the cycle number in which defaults such as cracks are generated on the cured film is, the more excellent in a heat impact resistance the cured film is.

### Semiconductor Element:

The semiconductor element according to the present invention has the cured film formed in the manner described above. The above cured film can suitably be used as a surface protective film, an interlayer insulation film and the like in the semiconductor element.

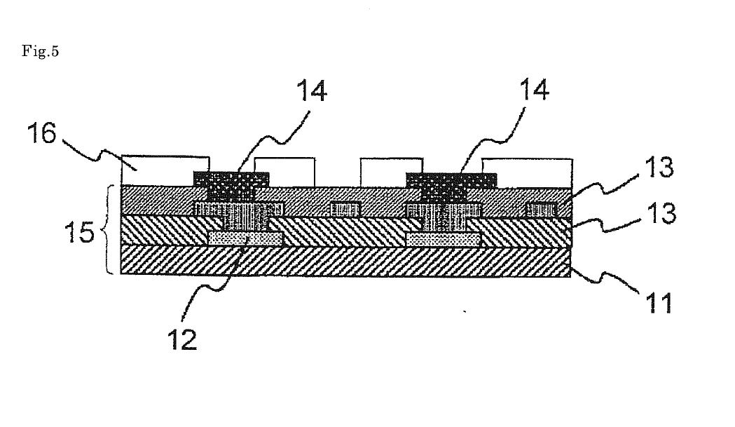

The semiconductor element described above includes, for example, semiconductor elements (circuit-provided substrates) shown in FIGS. 4 and 5. In the circuit-provided substrate shown in FIG. 4, a metal pad 12 is first formed in a pattern form on a substrate 11, and then an insulation film (cured film) 13 is formed thereon in a pattern form by using the resin composition described above. Next, a metal wiring 14 is formed in a pattern form, and an insulation film (cured film) 16 is further formed, whereby the circuit-provided substrate is obtained. The circuit-provided substrate shown in FIG. 5 is obtained by further forming a metal wiring 14 in a pattern form on the circuit-provided substrate shown in FIG. 4 and then forming the insulation film (cured film) 16 by using the resin composition described above.

### EXAMPLES

The present invention shall be explained below in details with reference to examples, but the present invention shall by no means be restricted by these examples. Parts in the following examples and comparative examples mean parts by mass unless otherwise described.

The respective characteristics of the cure product were evaluated by the following methods.

### Adhesive Property:

The resin composition was coated on a silicon wafer or a silicon wafer sputtered thereon with copper and heated at 120° C. for 5 minutes on a hot plate to prepare an even resin coating film having a thickness of 10 μm. Then, the coating film was exposed to a UV ray radiated from a high pressure mercury lamp by means of an aligner (MA-150, manufactured by Suss Mictotec Inc.) so that an exposure at a wavelength of 350 nm was 2,000 J/m², and it was heated (PEB) at 110° C. for 3 minutes on a hot plate. Then, the resin coating film was cured by heating at 200° C. for one hour in a convention oven to obtain a cured film. This cured film was treated for 168 hours on the conditions of a temperature of 121° C., a humidity of 100% and a pressure of 2.1 atmosphere by means of a pressure cooker test equipment (manufactured by Tabai Espec Corp.). An adhesive property thereof before and after the test was evaluated by carrying out a crosscut test (a crosscut tape method) according to JIS K5400.

### Electric Insulation Property:

The resin composition was coated on a silicon substrate to form an insulation film, and a pattern-like copper foil 1 shown in FIG. 3 was formed thereon to prepare a substrate 3 for evaluating an electric insulation property. Both of a line space and a line width of the copper foil 1 were 20 μm. The resin composition was further coated on the substrate 3 for evaluating an electric insulation property and heated at 110° C. for 3 minutes by means of a hot plate to prepare a resin coating film having a thickness of 10 μm on a copper foil 4. Then, the coating film was exposed to a UV ray radiated from a high pressure mercury lamp by means of the aligner (MA-150, manufactured by Suss Mictotec Inc.) so that an exposure at a wavelength of 350 nm was 2,000 J/m², and it was heated (PEB) at 110° C. for 3 minutes on a hot plate. Then, the resin coating film was cured by heating at 200° C. for one hour in a convention oven to obtain the substrate having the cured film. The above substrate was put in a migration evaluation system (manufactured by Tabai Espec Corp.) and treated for 200 hours on the conditions of a temperature of 121° C., a humidity of 85%, a pressure of 1.2 atmosphere and an applied voltage of 5 V. Then, a resistance value (Ω) thereof was measured to confirm an insulation property of an upper layer in the cured film.

### Heat Impact Resistance:

The resin composition was coated on a substrate 3 for evaluating a heat impact resistance which had a pattern-like copper foil on a substrate 2 shown in FIG. 2 and heated at 110° C. for 3 minutes by means of a hot plate to prepare a resin coating film having a thickness of 10 μm on a copper foil 1. Then, the coating film was exposed to a UV ray radiated from a high pressure mercury lamp by means of the aligner (MA-150, manufactured by Suss Mictotec Inc.) so that an exposure at a wavelength of 350 nm was 2,000 J/m², and it was heated (PEB) at 110° C. for 3 minutes on a hot plate. Then, the resin coating film was cured by heating at 200° C. for one hour in a convention oven to obtain the substrate having the cured film. The above substrate was subjected to a tolerant test in which −55° C./30 minutes to 150° C./30 minutes was one cycle by means of a thermal shock test device (manufactured by Tabai Espec Corp.). A cycle number in which defaults such as cracks were generated on the cured film was confirmed every 100 cycles.

### Synthetic Example 1

### Synthesis of p-hydroxystyrene/styrene Copolymer

Total 100 parts by mass of p-t-butoxystyrene and styrene was dissolved in a proportion of 80:20 in 150 parts by mass of propylene glycol monomethyl ether, and they were polymerized at a reaction temperature held at 70° C. for 10 hours under nitrogen atmosphere using 4 parts by mass of azobisisobutyronitrile. Then, sulfuric acid was added to the reaction liquid to carry out reaction for 10 hours while holding the reaction temperature at 90° C., and p-t-butoxystyrene was deblocked and converted into p-hydroxystyrene. Ethyl acetate was added to the copolymer obtained, and the solution was washed repeatedly five times with water. The ethyl acetate phase was separated, and the solvent was removed to obtain a p-hydroxystyrene/styrene copolymer (hereinafter referred to as the “copolymer (A-1)”).

A molecular weight of the above copolymer (A-1) was measured by a gel permeation chromatography (GPC) to find that the weight average molecular weight (Mw) in terms of polystyrene was 10,000 and that a ratio (Mw/Mn) of the weight average molecular weight (Mw) to the number average molecular weight (Mn) was 3.5. The result obtained by ¹³C-NMR analysis showed that a copolymerization mole ratio of p-hydroxystyrene to styrene was 80:20.

### Synthetic Example 2

### Synthesis of p-hydroxystyrene/styrene/methyl methacrylate Copolymer

A p-hydroxystyrene/styrene methyl/methacrylate copolymer (hereinafter referred to as the “copolymer (A-2)”) was obtained in the same manner as in Synthetic Example 1, except that total 100 parts by mass of p-t-butoxystyrene, styrene and methyl methacrylate was dissolved in a proportion of 80:20:10 in 150 parts by mass of propylene glycol monomethyl ether.

The above copolymer (A-2) had a molecular weight of 10,000 and Mw/Mn of 3.5, and a copolymerization mole ratio of p-hydroxystyrene:styrene:methyl methacrylate was 80:10:10.

### Synthetic Example 3

### Synthesis of p-hydroxystyrene Homopolymer

A p-hydroxystyrene homopolymer (hereinafter referred to as the “homopolymer (A-3)”) was obtained in the same manner as in Synthetic Example 1, except that 100 parts by mass of only p-t-butoxystyrene was dissolved in 150 parts by mass of propylene glycol monomethyl ether.

The above homopolymer (A-3) had a molecular weight of 10,000 and Mw/Mn of 3.5.

### Synthetic Example 4

### Synthesis of p-hydroxystyrene/methacrylic Acid Copolymer

A p-hydroxystyrene/methacrylic acid copolymer (hereinafter referred to as the “copolymer (A-4)”) was obtained in the same manner as in Synthetic Example 1, except that total 100 parts by mass of p-t-butoxystyrene and methacrylic acid was dissolved in a proportion of 90:10 in 150 parts by mass of propylene glycol monomethyl ether.

The above copolymer (A-4) had a molecular weight of 10,000 and Mw/Mn of 3.7, and a copolymerization mole ratio of p-hydroxystyrene:methacrylic acid was 90:10.

### Synthetic Example 5

### Synthesis of Phenol Resin (a-1)

m-Cresol was mixed with p-cresol in a proportion of a mole ratio 60:40, and formalin was added thereto to carry out condensation by an ordinary method under the presence of an oxalic acid catalyst, whereby a cresol novolac resin (hereinafter referred to as the “phenol resin (a-1)”) having Mw of 6,500 was obtained.

### Examples 1 to 4

The copolymer (A), the cross-linking agent (B), the photoacid generator (C), the adhesion auxiliary agent (E) and the cross-linked fine particles (F) which were shown in Table 1 were dissolved in the solvent (D) in amounts each shown in Table 1 to prepare a photosensitive insulation resin composition. This resin composition was used to prepare a cured film according to the method described in the evaluation methods described above.

The characteristics of the resin composition and the cured film were measured according to the evaluation methods described above. The results thereof are shown in Table 2.

### Comparative Examples 1 to 5

Resin compositions comprising components shown in Table 1 and cured films thereof were prepared in the same manner as in Example 1. The characteristics of the resin compositions and the cured films were measured in the same manner as in Example 1. The results thereof are shown in Table 2.

TABLE 1

| | | Phenol | | | Acid | | Adhesion | Cross-linked |
|---|---|---|---|---|---|---|---|---|
| | (Co)polymer | compound | Cross-linking | | generator | | auxiliary | fine particles |
| | (A) | (a) | agent (B) | | (C) | Solvent (D) | agent (E) | (F) |
| | Kind:part | Kind:part | Kind:part | Kind:part | Kind:part | Kind:part | Kind:part | Kind:part |
| Example 1 | A-1:100 | — | B1-1:20 | B2-3:20 | C-1:3 | D-1:150 | E-1:3 | F-1:10 |
| Example 2 | A-1:80 | a-1:20 | B1-2:20 | B2-1:20 | C-2:3 | D-1:150 | E-2:3 | F-1:10 |
| Example 3 | A-1:60 | a-2:40 | B1-1:20 | B2-2:20 | C-1:2 | D-1:150 | E-1:3 | F-1:10 |
| Example 4 | A-2:100 | — | B1-1:20 | B2-1:20 | C-1:3 | D-2:150 | E-1:3 | F-2:10 |
| Comparative | A-3:100 | — | B1-1:20 | B2-1:20 | C-1:3 | D-1:150 | E-1:3 | F-1:10 |
| Example 1 | | | | | | | | |
| Comparative | A-4:100 | — | B1-1:20 | B2-1:20 | C-1:3 | D-1:150 | E-1:3 | F-1:10 |
| Example 2 | | | | | | | | |
| Comparative | A-1:100 | — | — | — | C-1:3 | D-1:110 | E-2:3 | F-1:10 |
| Example 3 | | | | | | | | |
| Comparative | A-1:100 | — | B1-1:20 | B2-1:20 | C-1:3 | D-1:150 | — | F-1:10 |
| Example 4 | | | | | | | | |
| Comparative | A-1:100 | — | B1-1:20 | B2-1:20 | C-1:3 | D-1:150 | E-1:3 | — |
| Example 5 | | | | | | | | |

Remark: the respective components show the following compounds.

### (Co)Polymer (A)

A-1: copolymer comprising p-hydroxystyrene/styrene=80/20 (mole ratio), Mw=10,000, Mw/Mn=3.5
A-2: copolymer comprising p-hydroxystyrene/styrene/methyl methacrylate=80/10/10 (mole ratio), Mw=10,000, Mw/Mn=3.5
A-3: homopolymer of p-hydroxystyrene, Mw=10,000, Mw/Mn=3.5
A-4: copolymer comprising p-hydroxystyrene/methacrylic acid=90/10 (mole ratio), Mw=10,000, Mw/Mn=3.7
a-1: cresol novolac resin comprising m-cresol/p-cresol=60/40 (mole ratio), Mw=6,500
a-2: 1,1-bis(4-hydroxyphenyl)-1-{4-[1-(4-hydroxyphenyl)-1-methylethyl]phenyl}ethane

### Cross-Linking Agent (B):

Oxetanyl group-containing compound (B1):
B1-1: 1,4-bis{[(3-ethyloxetane-3-yl)methoxy]methyl}benzene (trade name: OXT-121, manufactured by Toagosei Co., Ltd.)
B1-2: 3-ethyl-3-{[(3-ethyloxetane-3-yl)methoxy]methyl}oxetane (trade name: OXT-221, manufactured by Toagosei Co., Ltd.)
B2-1: pentaerythritol glycidyl ether (trade name: Denacol EX411, manufactured by Nagase ChemteX Corporation)
B2-2: propylene glycol diglycidyl ether (trade name: Epolite 70P, manufactured by Kyoeisha Chemical Co., Ltd.)
B2-3: sorbitol polyglycidyl ether (trade name: Denacol EX610U, manufactured by Nagase ChemteX Corporation)

### Photoacid Generator (C):

C-1: 4-(phenylthio)phenyldiphenylsulfonium tris(pentafluoroethyl)trifluorophosphate (trade name: CPI-210S, manufactured by SAN-APRO LIMITED)
C-2: 4-(phenylthio)phenyldiphenylsulfonium hexafluoroantimonate (trade name: CPI-101A, manufactured by SAN-APRO LIMITED)

### Solvent (D):

D-1: ethyl lactate

### D-2: N-methylpyrrolidone

### Adhesion Auxiliary Agent (E):

E-1: γ-glycidoxypropyltrimethoxysilane (trade name: S-510, manufactured by Chisso Corporation)
E-2: 1,3,5-N-tris(trimethoxysilyl) isocyanurate (trade name: Y11597, manufactured by GE Toshiba Silicone Co., Ltd.)

### Cross-Linked Fine Particle (F):

F-1: butadiene/hydroxybutyl methacrylate/methacrylic acid/divinylbenzene=60/32/6/2 (% by mass), Tg=−40° C., average particle diameter=65 nm
F-2: butadiene/styrene/hydroxybutyl methacrylate/divinylbenzene=60/24/14/2 (% by mass), Tg=−35° C., average particle diameter=70 nm

TABLE 2

| | | | Heat impact | Insulation |
|---|---|---|---|---|
| | Adhesive property | | resistance | property |
| | Silicon | Copper | (cycle) | (Ω) |
| Example 1 | 100/100 | 100/100 | 2,000 | 1 × 10¹² |
| Example 2 | 100/100 | 100/100 | 2,000 | 1 × 10¹² |
| Example 3 | 100/100 | 100/100 | 2,000 | 1 × 10¹² |
| Example 4 | 100/100 | 100/100 | 2,000 | 1 × 10¹² |
| Comparative | 100/100 | 100/100 | 2,000 | 1 × 10⁶ |
| Example 1 | | | | |
| Comparative | 100/100 | 100/100 | 2,000 | 1 × 10⁶ |
| Example 2 | | | | |
| Comparative | 0/100 | 0/100 | 100 | 1 × 10⁶ |
| Example 3 | | | | |
| Comparative | 60/100 | 40/100 | 1,000 | 1 × 10⁶ |
| Example 4 | | | | |
| Comparative | 100/100 | 100/100 | 1,000 | 1 × 10¹² |
| Example 5 | | | | |

### INDUSTRIAL APPLICABILITY

Using the photosensitive insulation resin composition according to the present invention makes it possible to form a cured product which is excellent in an insulation property, a heat impact resistance, an adhesive property and the like and makes it possible to obtain particularly a semiconductor element having an interlayer insulation film and a surface protecting layer which are excellent in an insulation property, a heat impact resistance, an adhesive property and the like.

1. A photosensitive insulation resin composition characterized by comprising (A) a copolymer comprising 10 to 99 mole % of a constitutional unit (A1) represented by the following Formula (1) and 90 to 1 mole % of a constitutional unit (A2) represented by the following Formula (2) (provided that the total of all constitutional units constituting the above copolymer (A) is 100 mole %): 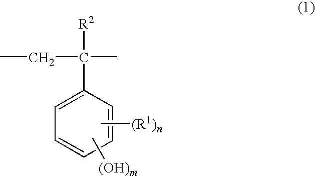
(wherein R¹ represents an alkyl group having 1 to 4 carbon atoms, an alkoxy group or an aryl group; R² represents a hydrogen atom or methyl; m is an integer of 1 to 3, and n is an integer of 0 to 3; and m+n≦5): 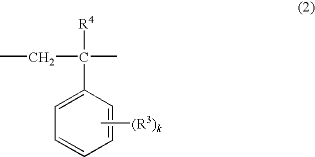
(wherein R³ represents an alkyl group having 1 to 4 carbon atoms, an alkoxy group or an aryl group; R⁴ represents a hydrogen atom or methyl; and k is an integer of 0 to 3),
(B) a compound (B1) having an oxetanyl group,
(C) a photosensitive acid generator,
(D) a solvent and
(F) cross-linked fine particles.

2. The photosensitive insulation resin composition as described in claim 1, wherein the copolymer (A) comprises 70 to 95 mole % of the constitutional unit (A1) represented by Formula (1) described above (provided that the total of all constitutional units constituting the above copolymer (A) is 100 mole %).

3. The photosensitive insulation resin composition as described in claim 1, further comprising a compound (B2) having an epoxy group.

4. The photosensitive insulation resin composition as described in claim 3, wherein assuming that the total of the compound (B1) having an oxetanyl group and the compound (B2) having an epoxy group is 100 parts by mass, a content of the compound (B1) having an oxetanyl group is 40 to 60 parts by mass, and a content of the compound (B2) having an epoxy group is preferably is 60 to 40 parts by mass.

5. The photosensitive insulation resin composition as described in claim 1, wherein the constitutional unit (A2) is represented by the following Formula (2′):

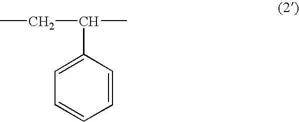

6. The photosensitive insulation resin composition as described in claim 1, further comprising a phenol compound (a).

7. The photosensitive insulation resin composition as described in claim 1, wherein the cross-linked fine particles (F) have an average particle diameter of 30 to 500 nm, and at least one of copolymers constituting the above cross-linked fine particles (F) has a glass transition temperature of 0° C. or lower.

8. The photosensitive insulation resin composition as described in claim 1, wherein a content of the cross-linked fine particles (F) described above is 0.1 to 50 parts by mass based on total 100 parts by mass of the copolymer (A) and the phenol compound (a).

9. The photosensitive insulation resin composition as described in claim 1, further comprising an adhesion auxiliary agent (E).

10. A cured product obtained by using the photosensitive insulation resin composition as described in claim 1.

11. A semiconductor element having a cured insulation film formed by using the photosensitive insulation resin composition as described in claim 1.
